(19) United States
(12) Patent Application Publication
(10) Pub. No.: US 2013/0183841 A1
(43) Pub. Date: Jul. 18, 2013

(54) USB STICK WITH HINGEDLY MOUNTED USB CONNECTOR

(71) Applicants: Thomas Stevens, Schaarbeek (BE); Jon Jacobson, Saint-Remy-Geest (BE)

(72) Inventors: Thomas Stevens, Schaarbeek (BE); Jon Jacobson, Saint-Remy-Geest (BE)

(73) Assignee: OPTION, Leuven (BE)

(21) Appl. No.: 13/812,312

(22) PCT Filed: Jul. 26, 2011
(86) PCT No.: PCT/IB11/53331

§ 371 Date: Mar. 25, 2013

(30) Foreign Application Priority Data
Jul. 26, 2010 (BE) 2010/0464

(51) Int. Cl. H05K 5/02

(52) U.S. Cl. CPC H05K 5/0286
USPC 439/131

(57) ABSTRACT

The invention relates to a USB stick comprising an oblong body which comprises electronic components and a USB connector electrically connected to the electronic components, the oblong body comprising a first part and a second part which are fixed to each other by means of a hinge connection, the first part comprising the USB connector and being rotatable with respect to the second part between a storage position in which the USB connector is stored inside the oblong body and a first use position in which the USB connector extends from the oblong body, the hinge mechanism comprising a spring mechanism for moving the first part. The electronic components are included in the second part of the oblong body and the USB connector is connected through to the second part by means of a connecting cable at the hinge connection.

### TECHNICAL FIELD

The present invention relates to a USB stick according to the preamble of the first claim.

### BACKGROUND ART

A USB stick generally comprises an oblong body in which electronic components are provided and a USB connector, which is electrically connected to the electronic components and is provided for connecting the USB stick with a USB port of an electronic device, mostly a computer. It is common that a protective cover is provided which can be moved over the USB connector in order to protect it when the USB stick is not in use. Different ways to do this are known, for example from US 2008/0019090 A1 and US 2010/0075517 A1, wherein this protective cover is carried out as an outer part of the oblong body which is rotatably mounted on an inner part of the oblong body, which comprises the USB connector.

It is a disadvantage of these known devices that all the electronic components of the USB sticks form part of the connector part, so that for another type of USB stick the electronic part has to be completely developed from scratch.

### DISCLOSURE OF THE INVENTION

It is an aim of this invention to provide a USB stick of the type with rotatable protection for the USB connector, of which the design is more easily reusable for different types of USB sticks.

According to the present invention, the aforementioned aim is achieved with a USB stick which shows all the characteristics of the first claim.

According to the invention, the electronic components are included in the second part of the oblong body and the USB connector is connected through to the second part by means of a connecting cable at the hinge connection. Such constructions have the advantage that the volume of the first part is essentially reduced to only the USB connector. As a result, this first part together with the connecting cable, becomes a module which is reusable for different types of USB sticks, more particularly a hingeable USB connector which can easily be built into various types of USB sticks.

In preferred embodiments according to the present invention, the first part is enclosed between complementary cover parts, which are in turn included in the second part of the oblong body. Such a construction has the advantage that a very robust construction can be achieved.

In preferred embodiments according to the present invention, one of the cover parts has a kidney-shaped opening at the hinge connection for the connecting cable. The kidney-shaped opening enables a movement of the connecting cable during the hinging of the first part with respect to the second part. Such a construction has the advantage that a very robust construction can be achieved.

In preferred embodiments according to the present invention, the oblong body comprises a housing which is provided with an upper decorative cover part and a lower decorative cover part, which are each provided with snap fixing means for releasably fixing them on the housing. Such a construction has the advantage that the modularity of the USB stick increases, as the decorative cover parts can be easily exchanged with other decorative cover parts and the user can for example personalize the USB stick with decorations of his choice.

### BRIEF DESCRIPTION OF THE DRAWINGS

The invention will be further elucidated by means of the following description and the appended drawings of a preferred embodiment of a USB stick according to the invention.

FIG. 1A shows a USB stick according to the invention, with the USB connector in the first use position.

FIG. 1B shows a USB stick according to the invention, with the USB connector in the second use position.

FIG. 2A shows a perspective view of a module with a hingable USB connector, built into the USB stick of FIG. 1A, with the USB connector being in the first use position.

FIG. 2B shows a perspective view of the module of FIG. 2A, in the storage position.

FIG. 3 shows an exploded view of the module of FIG. 2A.

FIG. 4A is a schematic view of the connection from the first part to an internal connector, via a connecting cable.

FIG. 4B shows a top view of the module of FIG. 2B in the storage position.

FIG. 4C shows a bottom view of the module of FIG. 2B in the storage position.

FIG. 4D shows a bottom view of the module of FIG. 2B but with the first part being in the second use position.

FIG. 4E shows a bottom view of the module of FIG. 2A in the first use position.

FIG. 5 shows a cross section of the module of FIG. 4C along the line V-V.

### MODES FOR CARRYING OUT THE INVENTION

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not necessarily correspond to actual reductions to practice of the invention.

Furthermore, the terms first, second, third and the like in the description and in the claims, are used for distinguishing between similar elements and not necessarily for describing a sequential or chronological order. The terms are interchangeable under appropriate circumstances and the embodiments of the invention can operate in other sequences than described or illustrated herein.

Moreover, the terms top, bottom, over, under and the like in the description and the claims are used for descriptive purposes and not necessarily for describing relative positions. The terms so used are interchangeable under appropriate circumstances and the embodiments of the invention described herein can operate in other orientations than described or illustrated herein.

The term “comprising”, used in the claims, should not be interpreted as being restricted to the means listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only recited components of the device are A and B, and the claim is further to be interpreted such that it also covers equivalents of these components.

Present electronic devices with a processor, e.g. a computer or a photo frame or a photo camera, often have a USB port to which an external device with a USB interface, such as a USB stick can be connected. The functionality of USB sticks can vary widely, for example the USB stick can comprise flash memory (so-called memory sticks), or electronics for a modem or a transmitter/receiver (e.g. for IR or Bluetooth signals) or other. The USB stick according to the shown embodiment conforms to one of the following USB standards: USB 1.0, USB 1.1, USB 2.0 or USB 3.0, and comprises a USB connector with four electric contacts.

USB sticks exist in a wide variety of shapes and dimensions. The shape is not purely determined by the volume of the electronics that the USB stick contains, but is often also different by its external design, both in shape and colour. Given the wide variety of such USB sticks, an attractive design or an additional functionality, such as a LED-light, is often a decisive feature which makes a buyer decide to buy the one USB stick instead of the other, which has furthermore the same functionality.

A lot of USB sticks contain a single PCB on which both the electric contacts of the USB connector and the electronic components are provided. Some of these USB sticks have a protective cover for protection of the USB connector when not in use. This protection can for example be a loose part, such as a fitting plastic cap which is to be placed manually over the connector, or it can be a rotatable part which is rotated by the user in front of the USB connector in order to protect the electric contacts.

The USB stick 14 shown in the figures offers a commercially attractive feature in that the USB stick 14 comprises a first part 19 with the USB connector 17, which first part 19 can rotate semi-automatically with respect to the remainder of the USB stick 14, further named the second part 20, when the user pushes an external button 27.

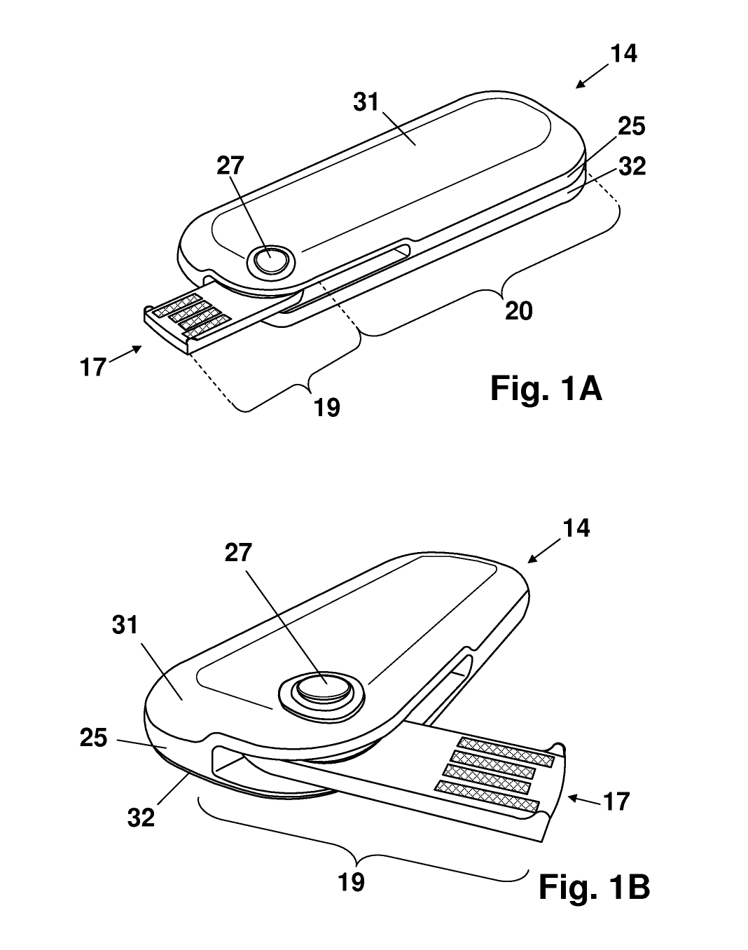

FIG. 1A shows such a USB stick 14, with the first part 19 with the USB connector 17 being in the first use position. In this case the first part 19 extends in an angle of 180° with respect to the remainder of the oblong body of the USB stick 14, named second part 20. An angle of 180° is particularly handy when multiple USB sticks are used next to each other on the same device, so that the USB sticks hinder each other as little as possible, physically or electrically.

FIG. 1B shows the same USB stick 14, but in a second use position, in which the first part 19 and the second part 20 extend in an angle of 90° with respect to each other. By this angle, the USB stick 14 can be positioned parallel to the side of a device (e.g. a computer) and protruding parts can be avoided as much as possible, which can minimise the risk of damage of the stick as well as the device.

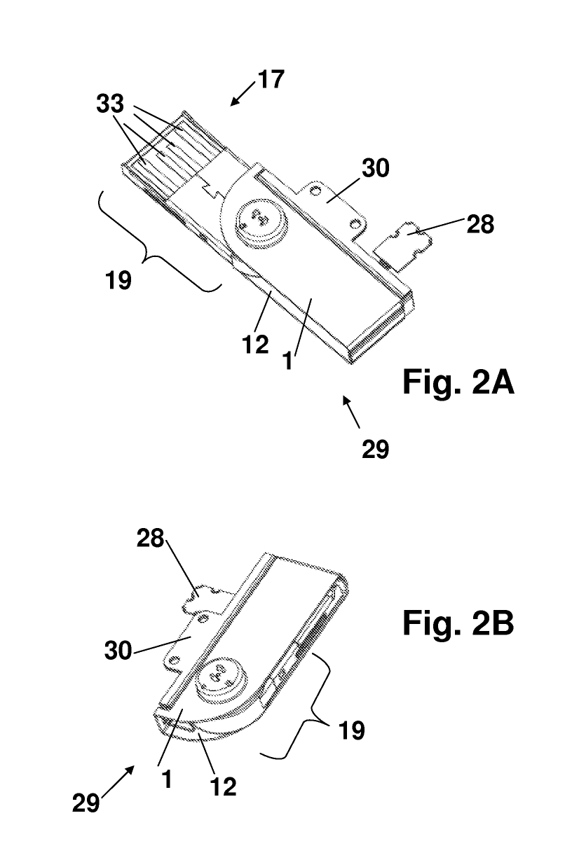

The USB stick 14 of FIG. 1A or FIG. 1B preferably contains a module 29 with the rotatable connector 17, which module 29 can be used in different types of USB sticks. FIG. 2A shows a preferred embodiment of such a module 29. The figure shows a module 29 with a hinge connection for holding a first part 19 on which a USB connector 17 is located, so that the first part 19 can rotate with respect to the remainder of the module 29, and when built into a USB stick 14, also with respect to the remainder of the USB stick 14. This module 29 is preferably built into a USB stick 14 with an oblong body made of a plastic housing 25, which is provided with an upper decorative cover part 31 and a lower decorative cover part 32. The module 29 is provided with a fixing rib 30 for fixing it to the housing of the USB stick 14. The fixing can for example occur by means of screws, or another known fixing method. The electric contacts 33 of the USB connector 17 are connected to the electronic components which are located in the second part 20 of the USB stick 14, by means of a connecting cable 13. Preferably the connecting cable is a four-wire cable, for connecting the supply line (VCC), the ground line (GND) and the two data lines (D+ and D−) of the USB connector 17. In the figures an end of the connecting cable 13 is connected to an internal connector 28, but this is not essential for the invention, since the connecting cable 13 can for example also be soldered.

FIG. 2B shows the module of FIG. 2A, but with the first part 19 in the storage position. In this position the USB connector 17 is located inside the module 29, which is in turn inside the housing of the USB stick 14, so that the electric contacts 33 cannot be damaged (e.g. by scratching or contamination) and the risk of dirt entering the USB connector 17 is minimized, contrary to classic USB sticks with manually rotatable protection in which the USB connector is not fully closed so that dust particles or the like can end up in the USB connector, which can lead to bad contact.

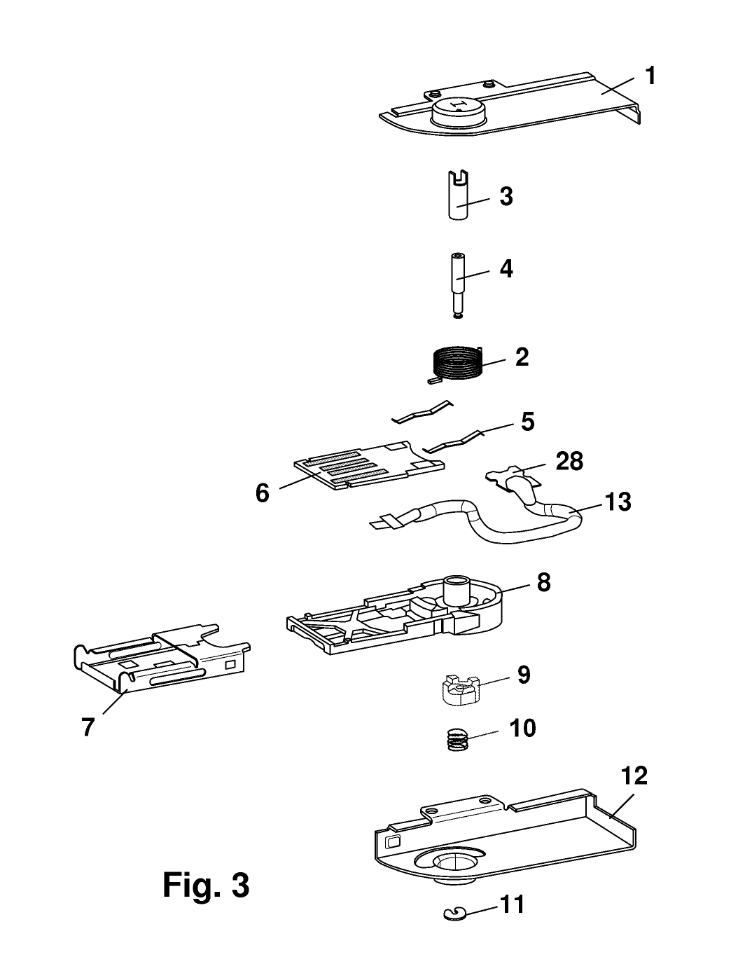

FIG. 3 shows an exploded view of the module 29 of FIG. 2A, which module 29 is built into the USB stick 14 of FIG. 1A. The module 29 comprises the following parts: a top cover part 1 and a bottom cover part 12, which are preferably made of an electrically conductive material, e.g. a metal, e.g. stainless steel. These cover parts are grounded with the ground of the USB connector 17. The top cover part 1 shows on the outside a fixing rib 30 for fixing the module 29 on the USB stick 14, but the fixing rib 30 could also be provided on the bottom cover part 12, or on both cover parts 1, 12. The cover parts each have a cylindrical protrusion for fixing the first part 19. The first part 19 comprises a rotatable USB body 8, a first PCB 6 with electric contacts 33, and a metal protection 7, the first PCB 6 and the metal protection 7 together forming the USB connector 17. The first part 19 can rotate with respect to the remainder of the module 29 by means of a hinge mechanism.

The hinge mechanism comprises among others a hollow shaft 3 which is mounted in a tubular opening of the USB body 8. Inside the hollow shaft 3 a pen 4 is mounted which is held between the top and bottom cover parts 1, 12 of the module 29. The hollow shaft 3 has two protrusions which extend through openings of the top cover part 1, to make contact with a user operable button 27. The hollow shaft 3 is further surrounded by a torsion spring 2, which makes sure that the first part 19 is thrown out when the button 27 is depressed.

The module 29 further comprises a blocking mechanism which makes sure that the first part 19 is held in one of the predetermined preferred positions. This blocking mechanism comprises among others a second spring 10 (e.g. an axial spring) which pushes onto a cam block 9 with projections, which projections can engage complementary recesses of the USB body 8. The cam block 9 and the USB body 8 together form two complementary cam members. The second spring 10 makes sure that the cam block 9 is pushed onto the USB body 8, so that blocking takes place. When the user pushes the button 27, the cam block 9 is removed from the USB body 8 so that the blocking is released and the USB body 8 can move outwards under the influence of the torsion spring 2, or inwards under the influence of a force exerted by the user. The button 27 and the hollow shaft 3 together form a releasing mechanism provided for pushing the complementary cam members 9 away from each other against the action of the second spring 10.

The module 29 further comprises spring contacts 5 for grounding the top and bottom cover parts 1, 20. The electric contacts 33 of the USB connector 17 are electrically connected to an internal connector 28 via a connecting cable 13. In this way the contacts 33 of the USB connector 17 can for example be connected to a second PCB (not shown, but also present in the oblong body of the USB stick 14) on which the electronic components are located. Note that the bottom cover part 12 has a kidney-shaped opening 23 for the movement of the connecting cable 13 which is fixed to the USB body 8.

At the end of the pen 4 an e-ring 11 is located which engages a groove of the pen 4, to keep the parts of the module 29 together. The function of the torsion spring 2 is to rotate the first part 19 with the USB connector 17 outwards with respect to the module 29. The function of the spring contacts (or slide contacts) 5 is to ground the top and bottom cover parts 1, 12. The spring contacts 5 can for example be attached to the cover parts 1, 12 by laser welding.

Note that the metal protection 7 is preferably half open; which is unusual for USB connectors, but this has the advantage that the USB stick 14 can be made thinner. This half open metal protection 7 is however not essential for the invention.

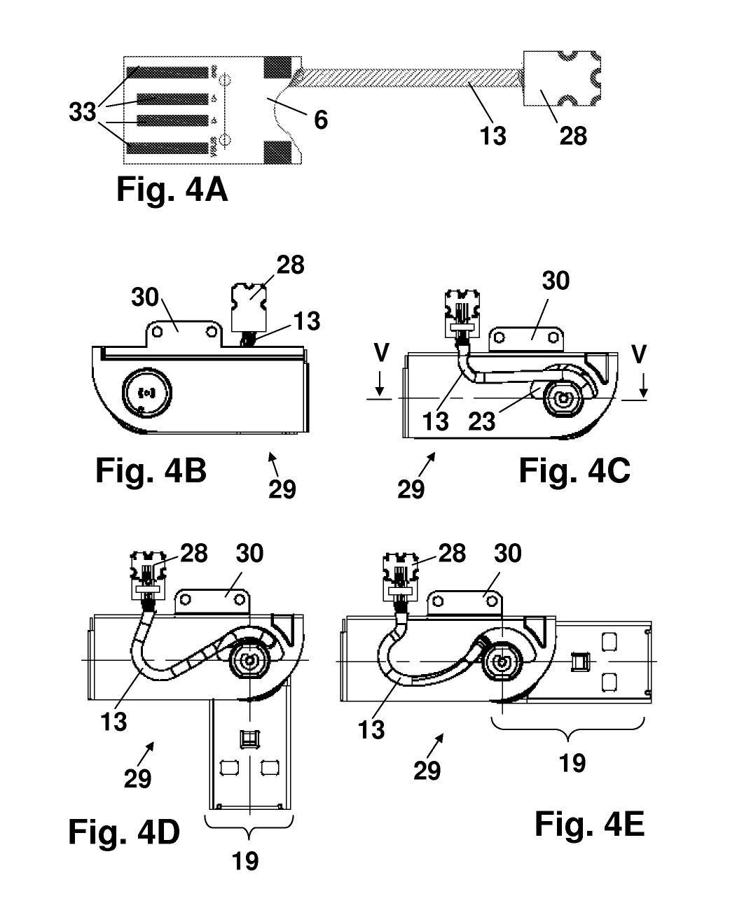

FIG. 4A is a schematic view of the connection of the first part 19 to an internal connector 28, via a connecting cable 13. The use of such an internal connector 28 is however not essential for the invention, and the connecting cable 13 can also be otherwise connected to the second PCB (not shown) on which the electronic components are provided, e.g. by directly soldering the connecting cable 31 to the second PCB.

FIG. 4B shows a top view of the mounted module 29 of FIG. 2B in the storage position.

FIGS. 4C-4E show a bottom view of the module 29 of FIG. 2B in which the first part 19 is respectively located in the storage position, the second use position and the first use position. Note the different positions of the connecting cable 13 for different positions of the first part 19. In the storage position the bend in the connecting cable is minimal.

FIG. 4D shows a bottom view of the module 29 with the first part 19 being in an angle of 90° with respect to the second part 20. One can clearly see that the connecting cable 13 is bent.

FIG. 4E shows a bottom view of the module 29 with the first part 19 being in an angle of 180° with respect to the second part 20. This is the first use position. In this position the bent in the connecting cable 13 is maximal.

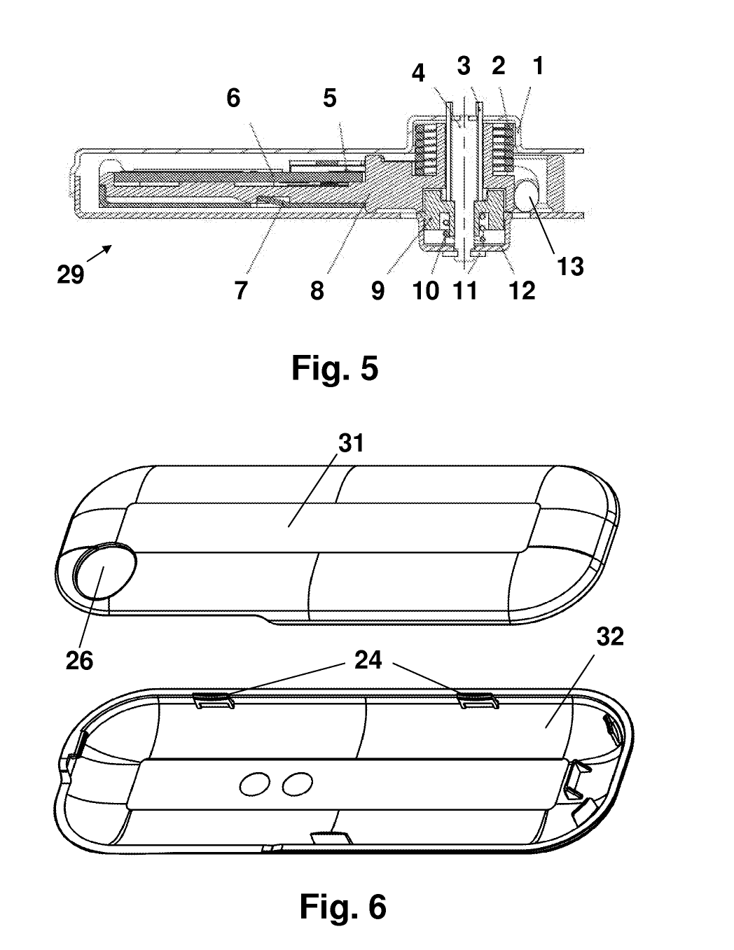

FIG. 5 shows a cross section of the module 29. The semi-automatic rotation system is explained by means of this figure. When the user pushes the button 27, which mechanically contact the hollow shaft 3, the hollow shaft 3 pushes the cam block 9 downwards, so that the pre-tensioned torsion spring 2 will rotate the first part 19 (with the USB body 8). The movement of the first part 19 will stop when the projections of the cam block 9 are engaged again into the complementary recesses of the USB body 8 under the influence of the axial spring 10. This can occur in the second use position, after a rotation over 90°, or in the first use position, after a rotation of 180° when the user keeps pushing the button 27 and the rotation is limited by the USB body 8 hitting an edge of the bottom cover part 12. When the user releases the button 27, the axial spring 10 will push the projections of the cam block 9 into the complementary recesses of the USB body 8, so that the position is blocked. The resistance of the blocking is chosen such, that the user can also manually (i.e. without operating the button 27) rotate the USB body 8 from the first or second use position to the other use position or the storage position, without damage. In the figure, four projections are shown, but this number is not essential for the invention.

The connecting cable 13 creates a robust electric contact between the USB connector 17 and the electronic components. This connection will even work when the first part 19 is rotated while the USB stick 14 is placed onto a device. Such a robustness is not offered when sliding contacts are used instead of a connecting cable 13.

FIG. 6 shows the decorative cover parts 31 and 32, which are each provided with snap fixing means 24 for releasably fixing them to the housing 25, more particularly resilient hook-shaped members 24 which snap into complementary recesses (not shown) on the housing. In this way, these decorative cover parts 31 and 32 are removable and exchangeable, so that the user can personalize the USB stick 14 with decorations of his choice. The upper cover part 31 has an opening 26 for the button 27.

1-6. (canceled)

7. USB stick comprising an oblong body which comprises electronic components and a USB connector electrically connected to the electronic components and provided for connecting the USB stick with a USB port of an electronic device, the oblong body comprising a first part and a second part which are fixed to each other by means of a hinge connection, the first part comprising the USB connector and being rotatable with respect to the second part between a storage position in which the USB connector is stored inside the second part of the oblong body and a first use position in which the USB connector extends from the second part of the oblong body, a user operable hinge mechanism being provided at the hinge connection for moving the first part with the USB connector from the storage position to the first use position, wherein the electronic components are included in the second part of the oblong body and the USB connector is connected through to the second part by means of a connecting cable at the hinge connection.

8. USB stick according to claim 7, wherein the first part is enclosed between two complementary cover parts which are included in the second part of the oblong body.

9. USB stick according to claim 8, wherein one of the cover parts has a kidney-shaped opening at the hinge connection for the connecting cable.

10. USB stick according to claim 7, wherein the hinge mechanism comprises a first spring, tensioned for causing the movement of the first part from the storage position to the first use position, a releasable blocking mechanism for releasably blocking the first part with the USB connector in the storage position, and a user accessible release mechanism, coupled to the blocking mechanism, for releasing the first part from the storage position.

11. USB stick according to claim 10, wherein the blocking mechanism comprises two complementary cam members, which are pushed onto each other by means of a second spring, and that the release mechanism is provided for pushing the complementary cam members away from each other against the action of the second spring.

12. USB stick according to claim 7, wherein the oblong body comprises a housing which is provided with an upper decorative cover part and a lower decorative cover part, which are each provided with snap fixing means for releasably fixing to the housing.

13. USB stick according to claim 7, wherein it comprises a housing and a module that can be fixed to the housing and that contains the rotatable connector and is built into the USB stick, wherein the module comprises the hinge connection that holds the first part on which the USB connector is located, so that the first part can rotate with respect to the remainder of the module and also with respect to the remainder of the USB stick.
